(19) United States
(12) Patent Application Publication
(10) Pub. No.: US 2022/0285158 A1
(43) Pub. Date: Sep. 8, 2022

(54) METHOD FOR FABRICATING SEMICONDUCTOR DEVICE

(71) Applicant: SK hynix Inc., Gyeonggi-do (KR)

(72) Inventors: Jae Chun CHA, Gyeonggi-do (KR); Kyeong Taek KIM, Gyeonggi-do (KR); Sung Hun SON, Gyeonggi-do (KR)

(21) Appl. No.: 17/496,335

(22) Filed: Oct. 7, 2021

(30) Foreign Application Priority Data
Mar. 5, 2021 (KR) 10-2021-0029459

(51) Int. Cl. H01L 21/28; H01L 21/8234; H01L 21/324

(52) U.S. Cl. CPC H01L 21/28052; H01L 21/823418; H01L 21/324

(57) ABSTRACT

The present invention provides a method for fabricating a semiconductor device capable of improving the contact resistance. According to an embodiment of the present invention, the method for fabricating the semiconductor device comprises: forming a doped region by doping and activation annealing a first dopant on a substrate; forming an interlayer insulating layer on the substrate; forming a contact hole exposing the doped region by etching the interlayer insulating layer; exposing the doped region to a pre-annealing; forming an additional doped region by doping a second dopant on a pre-annealed doped region; exposing the additional doped region to a post-annealing; and forming metal silicide on the additional doped region.

### CROSS-REFERENCE TO RELATED APPLICATIONS

The present application claims priority to Korean Patent Application No. 10-2021-0029459, filed on Mar. 5, 2021, which is herein incorporated by reference in its entirety.

### BACKGROUND

### 1. Field

The present invention relates to a semiconductor device, and, more particularly, to a method for fabricating the semiconductor device including a silicide.

### 2. Description of the Related Art

A metal silicide is formed to suppress the leakage current and an increase of the contact resistance during a semiconductor device fabrication. A contact structure has become finer, as semiconductor devices become smaller. That is, an open area of a contact hole has decreased, and a height of a contact hole has gradually increased.

Accordingly, there is a need for an improved method for further lowering the contact resistance as the semiconductor device becomes smaller.

### SUMMARY

Various embodiments of the present invention provide a method of fabricating a semiconductor device capable of improving the contact resistance.

According to an embodiment of the present invention, a method for fabricating a semiconductor device comprises: forming a doped region by doping and activation annealing a first dopant on a substrate; forming an interlayer insulating layer on the substrate; forming a contact hole exposing the doped region by etching the interlayer insulating layer; exposing the doped region to a pre-annealing; forming an additional doped region by doping a second dopant on a pre-annealed doped region; exposing the additional doped region to a post-annealing; and forming metal silicide on the additional doped region.

According to an embodiment of the present invention, a method for fabricating a semiconductor device comprises: forming an N-type source/drain region and a P-type source/drain region in a substrate; forming an interlayer insulating layer on the substrate; forming a contact hole respectively exposing the N-type source/drain region and the P-type source/drain region by etching the interlayer insulating layer; exposing the N-type and P-type source/drain regions to a pre-annealing; forming an N-type additional doped region by doping an N-type additional dopant in an annealed N-type source/drain region; forming a P-type additional doped region by doping a P-type additional dopant in an annealed P-type source/drain region; exposing the N-type and P-type additional doped regions to a post-annealing; and forming a metal silicide on each of he annealed N-type and P-type additional doped regions.

According to an embodiment of the present invention, a method for fabricating a semiconductor device comprises: forming an N-type source/drain region and a P-type source/drain region in a substrate; forming an interlayer insulating layer on the substrate; forming a contact hole respectively exposing the N-type source/drain region and the P-type source/drain region by etching the interlayer insulating layer; forming an N-type additional doped region by doping an N-type additional dopant in the N-type source/drain region; exposing the N-type additional doped region, the N-type source/drain region, and the P-type source/drain region to a pre-annealing; forming a P-type additional doped region by doping a P-type additional dopant in an annealed P-type source/drain region; exposing the N-type and P-type additional doped regions to the post-annealing; and forming a metal silicide on each of annealed N-type and P-type additional doped regions.

The present disclosure can improve the contact resistance of a source/drain region and a metal silicide by performing a pre-annealing process before an additional doping process and performing a post-annealing process after the additional doping process.

The present disclosure can improve the P-type contact resistance without deteriorating the N-type contact resistance by performing a high-temperature pre-annealing process before or after the additional doping process of the N-type dopant and by performing a low-temperature post-annealing process after an additional doping process of the P-type dopant.

The present disclosure can improve an operation speed of a semiconductor device and suppress leakage.

### BRIEF DESCRIPTION OF THE DRAWINGS

FIG. 1A is a flow chart illustrating a method for fabricating a semiconductor device according to an embodiment of the present invention.

FIG. 1B is a diagram illustrating the semiconductor device made according to the method of FIG. 1A.

FIGS. 2A to 2H are diagrams illustrating a method for fabricating a semiconductor device according to another embodiment of the present invention.

FIGS. 3A to 3G are diagrams illustrating a method for fabricating a semiconductor device according to another embodiment of the present invention.

FIGS. 4A to 4D are diagrams illustrating a method for fabricating a semiconductor device according to another embodiment of the present invention.

FIG. 5 is a diagram illustrating a semiconductor device according to another embodiment of the present invention.

### DETAILED DESCRIPTION

Various embodiments described herein will be described with reference to cross-sectional views, plane views and block diagrams, which are ideal schematic views of the present invention. Therefore, the structures of the drawings may be modified by fabricating technology and/or tolerances. The embodiments of the present invention are not limited to the specific structures shown in the drawings, but include any changes in the structures that may be produced according to the fabricating process. Also, any regions and shapes of regions Illustrated in the drawings have schematic views, are intended to illustrate specific examples of structures of regions of the various elements, and are not intended to limit the scope of the invention.

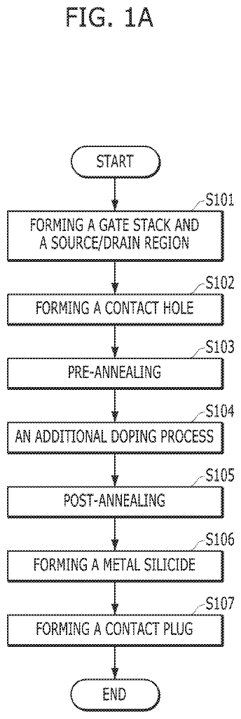

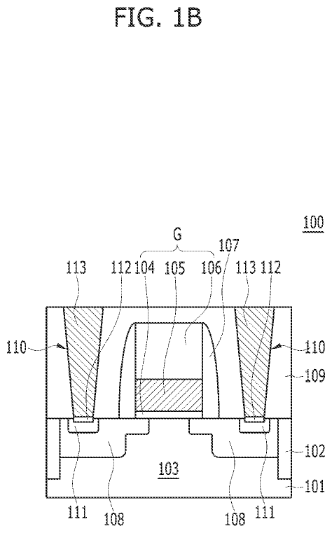

FIG. 1A is a flow chart illustrating a method for fabricating a semiconductor device according to an embodiment of the present invention. FIG. 1B is a diagram illustrating a semiconductor device made according to the method of FIG. 1A.

Referring to FIGS. 1A and 1B, a method for fabricating a semiconductor device 100 may include forming a gate stack and a source/drain region S101, forming a contact hole S102, pre-annealing process S103, an additional doping process S104, post-annealing process S105, forming a metal silicide S106, and forming a contact plug S107.

Referring to FIG. 1B again, device isolation layers 102 and active regions 103 may be formed in a substrate 101. A gate stack G may be formed on the active region 103. The gate stack G may include a gate insulating layer 104, a gate electrode 105, and a gate capping layer 106 stacked over the substrate 101 in the recited order. A spacer 107 may be formed on both sidewalls of the gate stack G.

The source/drain regions 108 may be formed on both sides of the gate stack Gin the active region 103. The source/drain regions 108 may be doped with a first dopant. The first dopant may include an N-type dopant. The first dopant may include a P-type dopant. An insulating layer 109 may be formed over the substrate 101. The insulating layer 109 may include contact holes 110 each passing through the insulating layer 109 to expose a corresponding one of the source/drain regions 108. An additional doped region 111 may be formed over a surface of the source/drain region 108. The additional doped region 111 may be doped with a second dopant. The second dopant may include an N-type dopant or a P-type dopant. The first dopant and the second dopant may be the same or different from each other. The contact hole 110 may expose a surface of the additional doped region 111. A metal silicide 112 may be formed on the surface of the additional doped region 111. A contact plug 113 may be formed on the metal silicide 112. The contact plug 113 may fill the contact hole 110.

As the additional doped region 111 is formed between the metal silicide 112 and the source/drain region 108, contact resistance may be improved.

As will be described later, the additional doped region 111 is carbon-free and fluorine-free, i.e., it may contain neither carbon nor fluorine. The additional doping process S104 may be performed to form the additional doped region 111 following the pre-annealing process S103. Post-annealing process S105 may also be performed after the additional doping process S104. Damages generated on the surface of the source/drain regions 108 during the forming of the contact hole S102 may be removed by the pre-annealing process S103.

The pre-annealing and the post-annealing process S103 and S105 may be performed at different temperatures. The method of heat treatment during the pre-annealing and the post-annealing process S103 and S105 may be of the same type but at different temperatures for each process. For example, the pre-annealing process S103 and the post-annealing process S105 may both include a rapid thermal process (RTP), however, the pre-annealing process S103 may be performed at a temperature higher than 950° C., while the post-annealing process S105 may be performed at a temperature of 950° C. or less. Performing the post-annealing process 25 at a temperature of 950° C. or less may be advantageous because it may suppress diffusion of impurities which are doped in the additional doped region 111.

In another embodiment, the pre-annealing process S103 and the post-annealing process S105 may be performed using different type thermal processes. For example, the pre-annealing process S103 may be performed by employing a rapid thermal process (RTP) such as a spike-rapid thermal annealing (spike-RTA), while the post-annealing process S105 may be performed by laser annealing or milli-second annealing. The post-annealing process S105 may be performed for a shorter time than the pre-annealing process S103. The pre-annealing process S103 and the post-annealing process S105 may each be performed at a temperature higher than 950° C., but the post-annealing process S105 may be performed at a temperature higher than the pre-annealing process S103 for less than about 1 second. Performing the post-annealing process S105 only for a short time of less than 1 second (for example for a few milliseconds) may suppress diffusion of dopants which are doped in the additional doped region 111. Short time annealing may be also referred to as milli-second annealing and may be advantageous over the rapid thermal process annealing. This is because, milli-second annealing is performed at a higher temperature than the rapid thermal process and for a very short time and, thus, diffusion of dopants may be further suppressed or minimized.

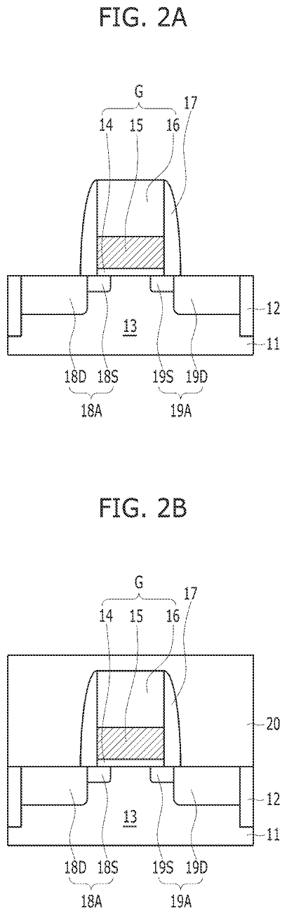

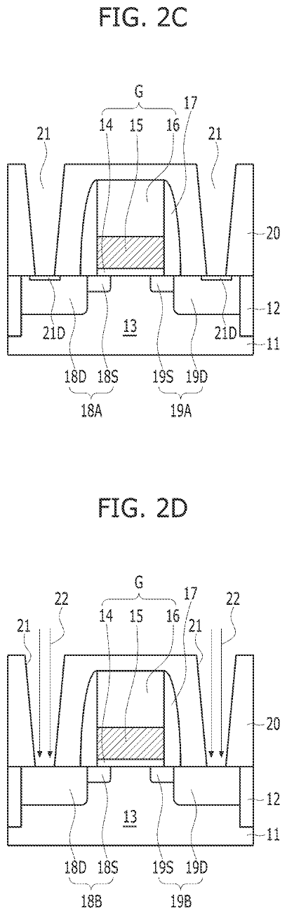

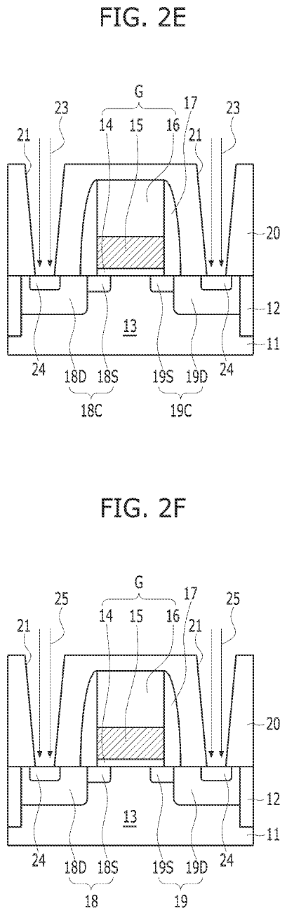

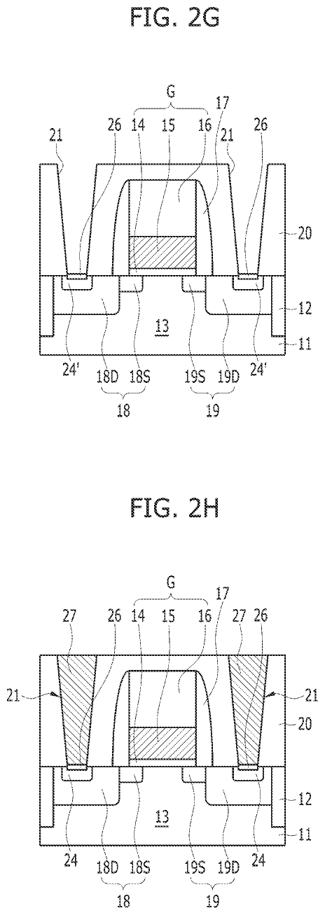

FIGS. 2A to 2H are cross-sectional views illustrating a method for fabricating a semiconductor device according to an embodiment of the present invention. A transistor is illustrated as an embodiment of a semiconductor device.

As shown in FIG. 2A, a device isolation layer 12 and an active region 13 may be formed in a substrate 11. The substrate 11 may be any material suitable for semiconductor processing. The substrate 11 may include a semiconductor substrate. The substrate 11 may be made of a material containing silicon. The substrate 11 may include silicon, monocrystalline silicon, polysilicon, amorphous silicon, silicon germanium, monocrystalline silicon germanium, polycrystalline silicon germanium, carbon-doped silicon, combinations thereof, or multiple layers thereof. The substrate 11 may also include other semiconductor materials such as germanium. The substrate 11 may include a III/V group semiconductor substrate, for example, a compound semiconductor substrate such as GaAs. The substrate 11 may include a silicon on insulator (SOI) substrate. The device isolation layer 12 may be a shallow trench isolation region (STI). The device isolation layer 12 may be formed by filling a shallow trench, for example, an isolation trench (not shown) with an insulating material. The device isolation layer 12 may include silicon oxide, silicon nitride, or a combination thereof. The active region 13 may have a bar-shape or a line-shape.

A gate stack G may be formed over the substrate 11. The gate stack G may include a gate insulating layer 14, a gate electrode 15, and a gate capping layer 16. A spacer 17 may be formed on both sidewalls of the gate stack G.

The gate insulating layer 14 may include silicon oxide, silicon nitride, silicon oxynitride, a high-k material, or a combination thereof. The high-k material may include a material having a dielectric constant greater than a dielectric constant of silicon oxide. For example, the high-k material may include a material having a dielectric constant greater than 3.9. In another example, the high-k material may include a material having a dielectric constant greater than 10. In another example, the high-k material may include a material having a dielectric constant of 10 to 30. The high-k material may include at least one metallic element. The high-k material may include a hafnium-containing material. The hafnium-containing material may include hafnium oxide, hafnium silicon oxide, hafnium silicon oxynitride, or a combination thereof. In another embodiment, the high-k material may include lanthanum oxide, lanthanum aluminum oxide, zirconium oxide, zirconium silicon oxide, zirconium silicon oxynitride, aluminum oxide, and a combination thereof. Other known high-k materials may be selectively used as a high-k material. The gate insulating layer 14 may be formed by stacking an interface layer and a high-k material. The interface layer may include silicon oxide, and the high-k material may include a hafnium-based material.

The gate electrode 15 may include one or more conductive materials, such as doped polysilicon, metal, metal alloy, silicide, or other suitable conductive materials. The gate electrode 15 may include a multi-layer structure having a multi-metal material. In another embodiment, the gate electrode 15 may include a material whose work function is tuned to obtain an improved threshold voltage. In some embodiments, the gate electrode 15 may be a material having a work function (4.5 eV or less) for an N-channel transistor. In another embodiment, the gate electrode 15 may be a material having a work function (4.5 eV or more) for a P-channel transistor. The gate capping layer 16 may include silicon oxide, silicon nitride, or a combination thereof. The spacer 17 may include silicon oxide, silicon nitride, or a combination thereof.

Doped regions may be formed in the active region 13 of the substrate 11. The doped regions may include a first source/drain region 18A and a second source/drain region 19A spaced apart from each other.

The first source/drain region 18A and the second source/drain region 19A may be formed by a doping process such as an implantation process. The first source/drain region 18A and the second source/drain region 19A may be doped with a first dopant such as an N-type dopant or a P-type dopant. For example, the first dopant may include phosphorus (P), arsenic (As), antimony (Sb), or boron (B). The first source/drain region 18A and the second source/drain region 19A may be doped with the first dopant of the same conductivity type. The first source/drain region 18A and the second source/drain region 19A may be an N-type source/drain region or a P-type source/drain region. The first source/drain region 18A and the second source/drain region 19A may include deep regions 18D and 19D, respectively, and shallow regions 18S and 19S, respectively. The shallow regions 18S and 19S may be referred to as a lightly doped drain (LDD) or a source drain extension (SDE). The shallow regions 18S and 19S may have a lower dopant concentration than the deep regions 18D and 19D. The shallow regions 18S and 19S may partially overlap with the gate stack G and the spacer 17. The shadow regions 18S and 19S may be spaced apart from each other leaving a region of the active region 13 between them positioned below the gate insulating layer 14 that is not doped. The shallow regions 18S and 19S may extend at a lower depth inside the substrate 11 than the deep regions 18D and 19D.

To form the first and second source/drain regions 18A and 19A, a doping process using the first dopant followed by activation annealing of the first dopant may be sequentially performed. Activation annealing may include rapid thermal annealing (RTA) at a temperature of 1000° C. or higher for a few seconds or less. The first and second source/drain regions 18A and 19A may include activated first dopants by activation annealing.

As shown in FIG. 2B, an interlayer insulating layer 20 may be formed on the substrate 11. The interlayer insulating layer 20 may include silicon oxide, silicon nitride, a low-k material, or a combination thereof. In this embodiment, the interlayer insulating layer 20 may be formed of a low-k material.

As shown in FIG. 2C, contact holes 21 may be formed in the interlayer insulating layer 20. For example, the contact holes 21 may be formed by performing contact etching. The contact holes 21 may expose respective surfaces of the first and second source/drain regions 18A and 19A. More specifically, the contact holes 21 may expose respective surfaces of the deep regions 18D and 19D of the first and second source/drain regions 18A and 19A. The contact holes 21 may be formed by photolithography and etching processes. In an embodiment, a patterned photoresist (not shown) may be formed, and the interlayer insulating layer 20 may be etched by a contact etching process using the patterned photoresist as an etching mask. The contact hole 21 may also be referred to as a contact opening. A sidewall of the contact hole 21 may have a vertical profile (not shown) or a tapered profile.

The contact etching process for forming the contact hole 21 may be performed using an etching gas including carbon (C), fluorine (F), or a combination thereof. For example, during the contact etching process, the etching gas may include a mixed gas of C₄F₈/Ar/O₂.

As described above, the contact etching process uses an etching gas containing carbon and fluorine, and a damaged portion 21D may be formed on the top surfaces of the first and second source/drain regions 18A and 19A, the damaged portion 21D being damaged by and containing carbon and fluorine. The damaged portion 21D may include substrate loss or a lattice defect. When the damaged portion 21D contains a large amount of carbon and fluorine, contact resistance may be deteriorated.

As shown in FIG. 2D, the damaged portion 21D and the first and second source/drain regions 18A and 19A may be exposed to a pre-annealing process indicated generally with arrows 22. The pre-annealing process 22 may be performed at a temperature similar to that of the activation annealing. For example, the pre-annealing process 22 may be performed at a temperature higher than 950° C. The pre-annealing process 22 may include a rapid thermal process (RTP). The pre-annealing process 22 may include a spike-RTP. The damaged portion 21D may be cured by the pre-annealing process 22. For example, if the pre-annealing process 22 is performed at a temperature higher than 950° C., the damaged portion 21D may be cured, and thus carbon and fluorine may be out-diffused. When the pre-annealing process 22 is performed, dopants doped in the first and second source/drain regions 18A and 19A may be re-activated. The pre-annealing process 22 may be performed at a temperature in the range of 951° C. to 1040° C. After the pre-annealing process 22 is performed, the first and second source/drain 18A and 19A may be referred to as a pre-annealed first and second source/drain 18B and 19B.

As the pre-annealing process 22 is performed, the pre-annealed first and second source/drain regions 18B and 19B may become carbon-free and fluorine-free surfaces.

As shown in FIG. 2E, an additional doping process indicated generally with arrows 23 may be performed on the pre-annealed first and second source/drain regions 18B and 19B. The additional doping process 23 may be performed to lower the contact resistance between the metal silicide (or contact plug) and the pre-annealed first and second source drain regions 18B and 19B.

The additional doping process 23 may include implanting a second dopant on the substrate 11. The additional doping process 23 may be performed on surfaces of the pre-annealed first and second source/drain regions 18B and 19B. After the additional doping process 23 is performed, the pre-annealed first and second source/drain 18B and 19B may be referred to as an additional-doped first and second source/drain 18C and 19C. An additional doped region 24′ may be formed in the surfaces of the additional-doped first and second source/drain regions 18C and 19C by the additional doping process 23. When the additional-doped first and second source/drain regions 18C and 19C are doped with an N-type dopant, the additional doping process 23 may employ dopants such as P, As, or Sb. The additional doped region 24′ may include N-type dopants having a higher concentration than the additional-doped first and second source/drain regions 18C and 19C.

In another embodiment, when the additional-doped first and second source/drain regions 18C and 19C are doped with a P-type dopant, the additional doping process 23 may include two doping processes. For example, a first additional doping process and a second additional doping process may be sequentially performed. The first and second additional doping processes may employ different second dopants. For example, the first additional doping process may use germanium, and the second additional doping process may use a P-type dopant such as boron. The first additional doping process may be performed with a germanium implantation, which may be referred to as a germanium pre-amorphous implantation (Ge PAI). In the case of the germanium implant, the degree of activation of the dopant in the additional-doped first and second source/drain regions 18C and 19C may be improved, and diffusion of the dopant may be controlled. In the second additional doping process, the boron-based material may be doped. The boron-based material may include B, BF₂, BF₃ or B₂H₆. The second additional doping process may be performed by an implantation process or plasma doping (PLAD). For example, in the case of B₂H₆, a large amount of boron may be doped in a short time through plasma doping (PLAD), and contact resistance characteristics are also very excellent. In another embodiment, an additional doping of germanium may be performed after the additional doping process of boron. In another embodiment, after omitting the first additional doping process, only the second additional doping process may be performed. When the additional-doped first and second source/drain regions 18C and 19C and the additional doped regions 24′ are doped with a P-type dopant, the additional doped regions 24′ may have a higher concentration of P-type dopants than the additional-doped first and second source/drain regions 18C and 19C.

As shown in FIG. 2F, the additional doped region 24′ and the additional-doped first and second source/drain regions 18C and 19C may be exposed to the post-annealing process 25. After the post-annealing process 25 is performed, the additional-doped first and second source/drain 18C and 19C may be referred to as a post-annealed first and second source/drain 18 and 19. After the post-annealing process 25 is performed, the additional doped region 24′ may be referred to as a post-annealed additional doped region 24. The post-annealed doped region 24 may be formed in the surfaces of the post-annealed first and second source/drain regions 18 and 19. The post-annealing process 25 may be performed at a lower temperature than the pre-annealing process 22. The post-annealing process 25 may be performed at a temperature of 950° C. or less. The post-annealing process 25 may include a rapid thermal process (RTP). Post-annealing process 25 may include a spike-RTP. Since the post-annealing process 25 is performed at a temperature of 950° C. or less, diffusion of the dopants of the post-annealed additional doped region 24 may be suppressed. Thus, the dopant concentration may be secured in the surfaces of the post-annealed first and second source/drain regions 18 and 19. That is, diffusion of dopants in the vertical and horizontal directions on the surfaces of the post-annealed first and second source/drain regions 18 and 19 may be minimized.

As a comparative example, when the pre-annealing process 22 is omitted and the post-annealing process 25 is performed by a rapid thermal process at a temperature above 950° C., the dopants may be out-diffused from the surfaces of the post-annealed first and second source/drain regions 18 and 19, thereby deteriorating the contact resistance.

As another comparative example, when both the pre-annealing process 22 and the post-annealing process 25 are performed by a rapid thermal process at a temperature above 950° C., the dopants may be out-diffused from the surfaces of the post-annealed first and second source/drain regions 18 and 19.

The post-annealing process 25 may be performed at a temperature in the range of 850° C. to 950° C.

Both the pre-annealing process 22 and the post-annealing process 25 may be performed by a rapid thermal process.

In another embodiment, the pre-annealing process 22 and the post-annealing process 25 may be performed with different types of thermal processes. For example, the pre-annealing process 22 may be performed by a spike-rapid thermal process, and the post-anneal 25 may be performed by laser annealing or milli-second annealing. The post-annealing process 25 may be performed in a shorter time than the pre-annealing process 22. The pre-annealing process 22 and the post-annealing process 25 each may be performed at a temperature above 950° C., but the post-annealing process 25 may be performed at a temperature higher than the pre-annealing process 22 for a time of less than about 1 second. Since the post-annealing process 25 is performed for a short time of less than 1 second, diffusion of the dopants doped to the post-annealed additional doped region 24 may be suppressed. Because the milli-second annealing anneals for a short time and uses a higher temperature than the spike-rapid thermal process, diffusion of the dopants may be minimized.

As shown in FIG. 2G, the metal silicide 26 may be formed over the post-annealed first and second source/drain regions 18 and 19 on which the post-annealing process 25 has been performed. Specifically, the metal silicide 26 may be formed over the post-annealed additional doped regions 24. The metal silicide 26 may be formed to cover the bottom of the contact holes 21. The metal silicide 26 may form a thin layer covering the bottom of the contact hole 21. The metal silicide 26 may be formed by a metal layer deposition and a heat treatment process (not shown). Subsequently, after the metal silicide 26 is formed, an unreacted metal layer may be removed. The metal silicide 26 may include titanium silicide or cobalt silicide. The metal silicide 26 may include silicide of a metal such as nickel. When the metal silicide 26 is formed, the post-annealed additional doped region 24 may be crystallized.

As shown in FIG. 2H, a contact plug 27 may be formed inside the contact hole 21. The contact plug 27 may include at least one of tungsten, titanium, and titanium nitride. The contact plug 27 may be formed over the metal silicide 26. The metal silicide 26 may contact the contact plug 27.

According to the above-described embodiment, a large amount of attack caused during a contact etching process for forming the contact hole 21 may be cured. For example, the contact etching process uses an etching gas containing carbon, fluorine, and so on. The damaged portion 21D caused by and containing the carbon and the fluorine may be formed on the surfaces of the first and second source/drain regions 18A and 19A. By performing the pre-annealing process 22, the damaged portion 21D may be cured, and deactivation of the pre-annealed first and second source/drain regions 18B and 19B may be compensated. Consequently, it is possible to increase the speed by improving the drive current and the contact resistance through the pre-annealing process 22. In addition, it is possible to improve leakage by reducing band-to-band tunneling or trap assisted tunneling through the pre-annealing process 22.

The dopant concentration of the surfaces of the post-annealed first and second source/drain regions 18 and 19 may be secured by the post-annealing process 25. Accordingly, contact resistance may be improved by increasing the dopant concentration at interfaces between the post-annealed first source/drain region 18 and the metal silicide 26 and between the post-annealed second source/drain region 19 and the metal silicide 26. In addition, the change in the threshold voltage may be reduced by reducing diffusion of dopants from the post-annealed first and second source/drain regions 18 and 19 to an edge of the gate electrode 15 through the post-annealing process 25.

In this embodiment, the contact resistances of the post-annealed first and second source/drain regions 18 and 19 and the contact resistance of the metal silicide 26 may be improved by performing the pre-annealing process 22 before the additional doping process 23 and by performing the post-annealing process 25 after the additional doping process 23. In addition, in this embodiment, the contact resistance may be improved even if the contact areas between the post-annealed first source/drain region 18 and the metal silicide 26 and between the post-annealed second source/drain region 19 and the metal silicide 26 decrease, and the gap between the contact plug 26 and the gate stack G decreases.

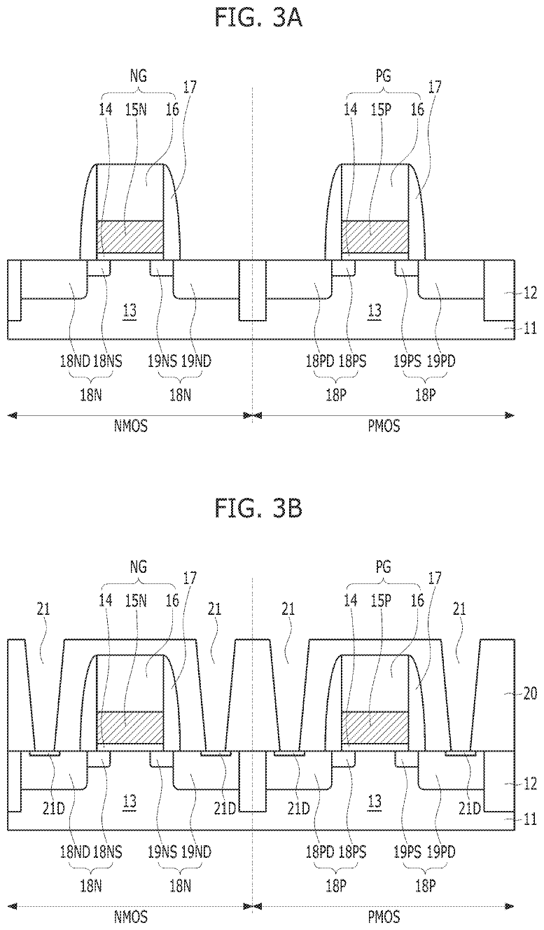

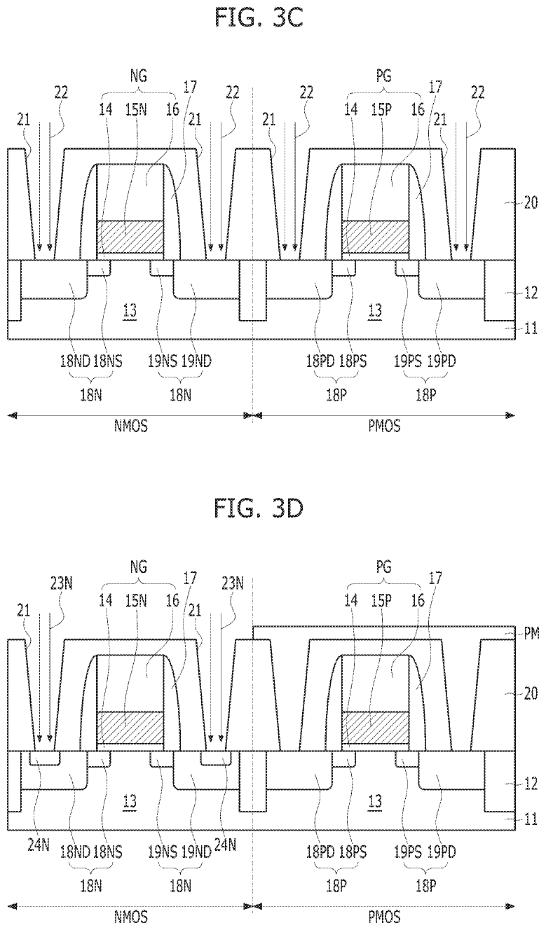

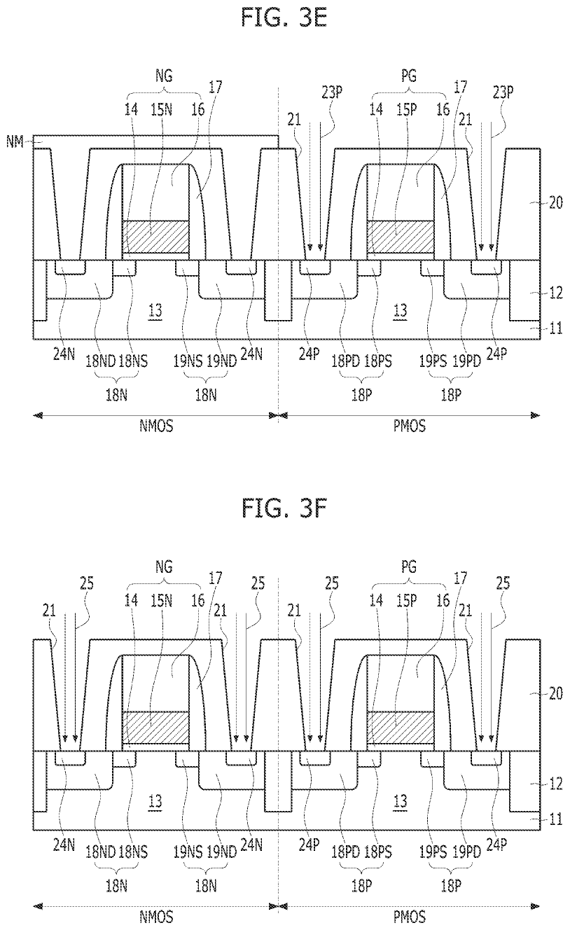

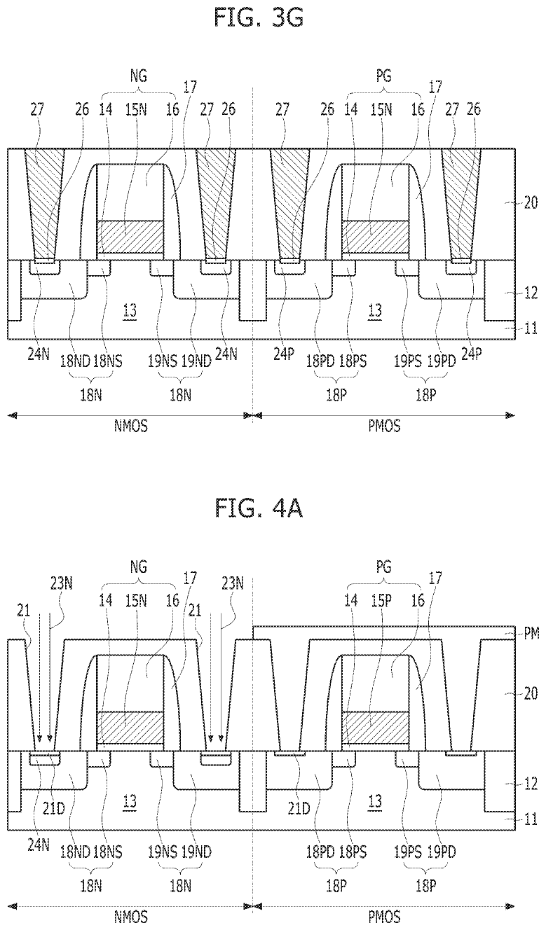

FIGS. 3A to 3G are cross-sectional views illustrating a method for fabricating a semiconductor device according to another embodiment. A complementary metal oxide semiconductor field effect transistor (CMOSFET) is shown as an example of a semiconductor device. In FIGS. 3A to 3G, the same reference numerals as in FIGS. 2A to 2H denote the same components.

As shown in FIG. 3A, a device isolation layer 12 and an active region 13 may be formed in a substrate 11. The substrate 11 may include an NMOS region NMOS and a PMOS region PMOS.

A plurality of gate stacks NG and PG may be formed over the substrate 11. The gate stacks NG and PG may include an N-type gate stack NG and a P-type gate stack PG. The N-type gate stack NG may be formed on the NMOS region NMOS of the substrate 11. The P-type gate stack PG may be formed on the PMOS region PMOS of the substrate 11. The N-type gate stack NG may include a gate insulating layer 14, an N-type gate electrode 15N, and a gate capping layer 16. A spacer 17 may be formed on both sidewalls of the N-type gate stack NG. The P-type gate stack PG may include the gate insulating layer 14, a P-type gate electrode 15P, and the gate capping layer 16. A spacer 17 may be formed on both sidewalls of the P-type gate stack PG.

The gate insulating layer 14 may include silicon oxide, silicon nitride, silicon oxynitride, a high-k material, or a combination thereof. The gate insulating layer 14 may be formed by stacking an interface layer and a high-k material. The gate capping layer 16 may include silicon oxide, silicon nitride, or a combination thereof. The spacer 17 may include silicon oxide, silicon nitride, or a combination thereof.

The N-type gate electrode 15N and the P-type gate electrode 15P may include one or more conductive materials, such as doped polysilicon, metal, metal alloy, silicide, or other suitable conductive materials. The N-type gate electrode 15N may be a material having a work function of 4.5 eV or less for an N-channel transistor, and the P-type gate electrode 15P may be a material having a work function of 4.5 eV or more for a P-channel transistor.

N-type and P-type source/drain regions 18N and 18P may be formed in the active region 13 of the substrate 11. The N-type source/drain region 18N may be formed in the active region 13 of the NMOS region NMOS, and the P-type source/drain region 18P may be formed in the active region 13 of the PMOS region PMOS.

The N-type source/drain region 18N may be doped with an N-type dopant, and the P-type source/drain region 18P may be doped with a P-type dopant. The N-type source/drain regions 18N may include deep regions 18ND and 19ND and shallow regions 18NS and 19NS. The P-type source/drain regions 18P may include deep regions 18PD and 19PD and shallow regions 18PS and 19PS. The shadow regions 18NS, 19NS, 18PS, and 19PS may be referred to as a lightly doped drain (LDD) or a source drain extension (SDE). The shallow regions 18NS, 19NS, 18PS, and 19PS may have a lower dopant concentration than the deep regions 18ND, 19ND, 18PD, and 19PD. The shallow regions 18NS, 19NS, 18PS, and 19PS may extend to a lower depth inside the substrate 11 than the deep regions 18ND, 19ND, 18PD, and 19PD. The shallow regions 18NS, 19NS, 18PS, and 19PS may partially overlap with respective gate stacks and spacers 17.

In order to form the N-type source/drain regions 18N and the P-type source/drain regions 18P, a dopant doping process and activation annealing may be sequentially performed. The activation annealing may include rapid thermal annealing (RTA) at a temperature of 1000° C. or higher.

As shown in FIG. 3B, an interlayer insulating layer 20 may be formed over the substrate 11. The interlayer insulating layer 20 may include silicon oxide, silicon nitride, a low-k material, or a combination thereof. In this embodiment, the interlayer insulating layer 20 may be formed of a low-k material.

Next, a contact etching process may be performed to form a contact hole 21 in the interlayer insulating layer 20. The contact hole 21 may expose portions of the N-type and P-type source/drain regions 18N and 18P. The contact hole 21 may be formed by photolithography and etching processes. In an embodiment, a patterned photoresist (not shown) may be formed, and the interlayer insulating layer 20 may be etched by a contact etching process using the patterned photoresist as an etching mask.

The contact etching process for forming the contact hole 21 may be performed using an etching gas including carbon (C), fluorine (F), or a combination thereof. For example, during the contact etching process, the etching gas may include a mixed gas of C₄F₈/Ar/O₂.

As described above, the contact etching process uses an etching gas containing carbon, fluorine, etc., and a damaged portion 21D caused by and containing the carbon and the fluorine may be formed on surfaces of the N-type and P-type source/drain regions 18N and 18P. The damaged portion 21D may include substrate loss or lattice defect. When the damaged portion 21D contains a large amount of carbon and fluorine, contact resistance may be deteriorated.

As shown in FIG. 3C, the pre-annealing process 22 may be performed. The pre-annealing process 22 may be performed at a temperature higher than 950° C. The pre-annealing process 22 may include a rapid thermal process (RTP). The damaged portion 21D may be cured by the pre-annealing process 22. For example, if the pre-annealing process 22 is performed at a temperature higher than 950° C., the damaged portion 21D may be cured, and thus the carbon and fluorine may be out-diffused. When the pre-annealing process 22 is performed, dopants doped in the N-type and P-type source/drain regions 18N and 18P may be re-activated.

As shown in FIG. 3D, after masking the contact holes 21 of the PMOS region PMOS (refer to the reference numeral ‘PM’), a first additional doping process 23N may be performed on the contact hole 21 of the NMOS region NMOS. That is, the first additional doping process 23N may be performed to lower the contact resistance between the metal silicide (or contact plug) and the N-type source drain region 18N. A material for masking PM the contact hole 21 of the PMOS region PMOS may include a photoresist.

The first additional doping process 23N may be performed to implant an additional dopant on the substrate 11. The first additional doping process 23N may be performed on the surface of the N-type source/drain region 18N. An N-type additional doped region 24N may be formed in the surface of the N-type source/drain region 18N through the first additional doping process 23N. In order to form the N-type additional doped region 24N, the doping process may be performed with an N-type dopant such as P, As, or Sb.

As shown in FIG. 3E, the masking PM may be removed. Next, after masking the contact hole 21 of the NMOS region NMOS (refer to the reference numeral ‘NM’), a second additional doping process 23P may be performed on the contact hole 21 of the PMOS region PMOS. That is, the second additional doping process 23P may be performed to lower the contact resistance between the metal silicide (or contact plug) and the P-type source drain region 18P. A material for masking NM the contact hole 21 of the NMOS region NMOS may include a photoresist. In the second additional doping process 23P, at least a P-type dopant may be doped.

The second additional doping process 23P may include two doping processes. For example, a germanium doping process and a boron doping process may be sequentially performed. The germanium doping process may be performed with a germanium implantation, and the boron doping process may be doped with a boron-based material such as B, BF₂, BF₃ or B₂H₆. The boron doping process may be performed by an implantation process or plasma doping (PLAD). For example, the boron doping process may be performed by B₂H₆ plasma doping (PLAD). In another embodiment, the germanium doping process may be performed after the boron doping process.

A P-type additional doped region 24P may be formed in the surface of the P-type source/drain region 18P by the second additional doping process 23P. The P-type additional doped region 24P may be doped with germanium and boron.

As shown in FIG. 3F, the post-annealing process 25 may be performed. The post-annealing process 25 may be performed at a lower temperature than the pre-annealing process 22. The post-annealing process 25 may be performed at a temperature of 950° C. or less. The post-annealing process 25 may include a rapid thermal process (RTP). Since the post-annealing process 25 is performed at a temperature of 950° C. or lower, the dopant concentration may be secured in the surfaces of the N-type and the P-type source/drain regions 18N and 18P by the N-type additional doped region 24N and the P-type additional doped region 24P. That is, diffusion of dopants in the surfaces of the N-type and P-type source/drain regions 18N and 18P may be prevented. As a comparative example, when the post-annealing process 25 is performed at a temperature higher than 950° C., dopants may be out-diffused at the surfaces of the N-type and P-type source/drain regions 18N and 18P, thereby deteriorating contact resistance.

In another embodiment, the pre-annealing process 22 and the post-annealing process 25 may be performed with different types of thermal process. For example, the pre-annealing process 22 may be performed by a spike rapid thermal process, and the post-annealing process 25 may be performed by laser annealing or milli-second annealing. The post-annealing process 25 may be performed for a shorter time than the pre-annealing process 22. The pre-annealing process 22 and the post-annealing process 25 each may be performed at a temperature higher than 950° C., but the post-annealing process 25 may be performed at a temperature higher than the pre-annealing process 22 for a time of less than about 1 second. Since the post-annealing process 25 is performed for a short time of less than 1 second, diffusion of dopants doped in the N-type and P-type source/drain regions 18N and 18P may be suppressed. The milli-second annealing has a higher temperature than the spike-rapid thermal process and is annealing for a short time, so diffusion of dopants may be minimized.

As shown in FIG. 3G, the metal silicide 26 may be formed on the N-type and P-type additional doped regions 24N and 24P. The metal silicide 26 may be formed by a metal layer deposition and a thermal process (not shown). Subsequently, after the metal silicide 26 is formed, an unreacted metal layer may be removed. The metal silicide 26 may include titanium silicide or cobalt silicide. The metal silicide 26 may include silicide of a metal such as nickel. When the metal silicide 26 is formed, the N-type and P-type additional doped regions 24N and 24P may be crystallized.

Next, the contact plug 27 may be formed. The contact plug 27 may include at least one of tungsten, titanium, and titanium nitride. The metal silicide 26 may contact the contact plug 27.

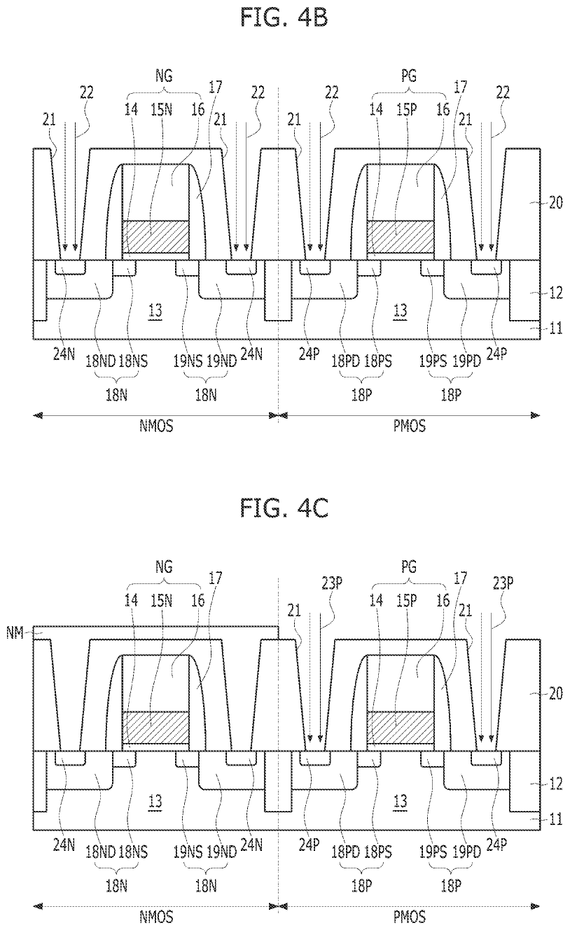

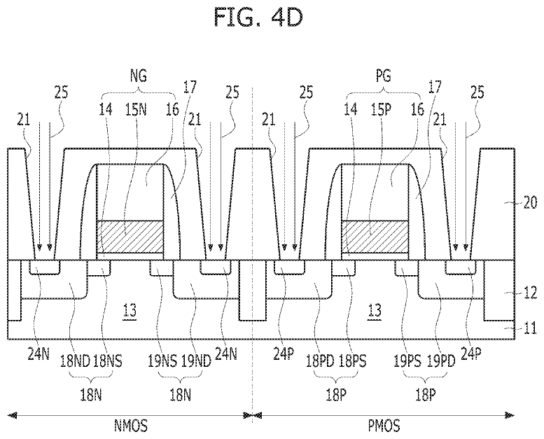

FIGS. 4A to 4D are cross-sectional views illustrating a method for fabricating a semiconductor device according to another embodiment. A CMOSFET is shown as an example of a semiconductor device. In FIGS. 4A to 4D, the same reference numerals as in FIGS. 3A to 3G denote the same components.

Referring to FIGS. 3A and 3B, a contact hole 21 may be formed in an interlayer insulating layer 20. The contact hole 21 may expose portions of N-type and P-type source/drain regions 18N and 18P. The contact hole 21 may be formed by photolithography and etching processes. In one embodiment, a patterned photoresist (not shown) may be formed, and the interlayer insulating layer 20 may be etched by a contact etching process using the patterned photoresist as an etching mask.

The contact etching process for forming the contact hole 21 may be performed using an etching gas including carbon (C), fluorine (F), or a combination thereof. For example, during the contact etching process, the etching gas may include a mixed gas of C₄F₈/Ar/O₂.

As above, the contact etching process uses an etching gas containing carbon, fluorine, and so on. A damaged portion 21D caused by and containing the carbon and the fluorine may be formed on surfaces of the N-type and P-type source/drain regions 18N and 18P. The damaged portion 21D may include a substrate loss or a lattice defect. When the damaged portion 21D contains a large amount of carbon and fluorine, contact resistance may be deteriorated.

As shown in FIG. 4A, after masking the contact hole 21 of the PMOS region PMOS (refer to the reference numeral ‘PM’), a first additional doping process 23N may be performed. That is, the first additional doping process 23N may be performed to lower the contact resistance between the metal silicide (or contact plug) and the N-type source drain region 18N. A material for masking PM the contact hole 21 of the PMOS region PMOS may include a photoresist.

The first additional doping process 23N may be performed to implant an additional dopant on the substrate 11. The first additional doping process 23N may be performed on a surface and the damaged portion 21D of the N-type source/drain region 18N. An N-type additional doped region 24N may be formed in the surface of the N-type source/drain region 18N by the first additional doping process 23N. The N-type additional doped region 24N may be doped with an N-type dopant such as P, As, or Sb.

As shown in FIG. 4B, after removing the masking PM, the N-type source/drain region 18N and the N-type additional doped region 24N may be exposed to the pre-annealing process 22. The pre-annealing process 22 may be performed at a temperature higher than 950° C. The pre-annealing process 22 may include rapid thermal annealing (RTA). The damaged portion 21D may be cured by the pre-annealing process 22. For example, if the pre-annealing process 22 is performed at a temperature higher than 950° C., the damaged portion 21D may be cured, and thus carbon and fluorine may be out-diffused. When the pre-annealing process 22 is performed, dopants doped in the N-type and P-type source/drain regions 18N and 18P may be re-activated.

As shown in FIG. 4C, after masking the contact hole 21 of the NMOS region NMOS (refer to the reference numeral ‘NM’), a second additional doping process 23P may be performed on the contact hole 21 of the PMOS region PMOS. That is, the second additional doping process 23P may be performed to lower the contact resistance between the metal silicide (or contact plug) and the P-type source drain region 18P. A material for masking NM the contact hole 21 of the NMOS region NMOS may include a photoresist. In the second additional doping process 23P, at least a P-type dopant may be doped.

The second additional doping process 23P may include two doping processes. For example, a germanium doping process and a boron doping process may be sequentially performed. The germanium doping process may be performed with a germanium implantation, and the boron doping process may be doped with a boron-based material such as B, BF₂, BF₃ or B₂H₆. The boron doping process may be performed by an implantation process or plasma doping (PLAD). For example, the boron doping process may be performed by B₂H₆ plasma doping (PLAD). In another embodiment, the germanium doping process may be performed after the boron doping process.

A P-type additional doped region 24P may be formed in the surface of the P-type source/drain region 18P by the second additional doping process 23P. The P-type additional doped region 24P may be doped with germanium and boron.

As shown in FIG. 4D, the N-type source/drain region 18N, the N-type additional doped region 24N, the P-type source/drain region 18P, and the P-type additional doped region 24P may be exposed to the post-annealing process 25. The post-annealing process 25 may be performed at a lower temperature than pre-annealing process 22. The post-annealing process 25 may be performed at a temperature of 950° C. or less. The post-annealing process 25 may include rapid thermal annealing (RTA). Since the post-annealing process 25 is performed at a temperature of 950° C. or less, the dopant concentration of the surfaces of the N-type and P-type source/drain regions 18N and 18P may be secured. That is, diffusion of dopants in the surfaces of the N-type and P-type source/drain regions 18N and 18P may be prevented. As a comparative example, when the post-annealing process 25 is performed at a temperature higher than 950° C., dopants may be out-diffused at the surfaces of the N-type and P-type source/drain regions 18N and 18P. Thus, contact resistance may be deteriorated.

In another embodiment, the pre-annealing process 22 and the post-annealing process 25 may be performed with different types of thermal processes. For example, the pre-annealing process 22 may be performed by spike-rapid thermal annealing. The post-annealing process 25 may be performed by laser annealing or milli-second annealing. The post-annealing process 25 may be performed for a shorter time than the pre-annealing process 22. The pre-annealing process 22 and the post-annealing process 25 may be performed at a temperature higher than 950° C., but the post-annealing process 25 may be performed at a temperature higher than the pre-annealing process 22 for a time of less than about 1 second. Since the post-annealing process 25 is performed for a short time of less than 1 second, diffusion of dopants doped in the N-type and P-type source/drain regions 18N and 18P may be suppressed. The milli-second annealing is performed at a higher temperature than the spike-rapid heat treatment and for a short time, so diffusion of dopants may be minimized.

Subsequently, as shown in FIG. 3G, a metal silicide 26 may be formed on the N-type and P-type additional doped regions 24N and 24P. Next, a contact plug 27 filling the contact hole 21 may be formed on the metal silicide 26.

In the embodiments according to FIGS. 3A to 4D, the contact resistances of the N-type source/drain region 18N and the metal silicide 26 (abbreviated as N-type contact resistance), and the contact resistances of the P-type source/drain region 18P and the metal silicide 26 (abbreviated as P-type contact resistance) may have a trade-off relationship. When the pre-annealing process 22 is omitted and the post-annealing process 25 of a temperature of 1000° C. or higher is performed after the second additional doping process 23P, the P-type contact resistance may be improved, but the N-type contact resistance may be deteriorated.

In the present embodiments, as the pre-annealing process 22 is performed before or after the first additional doping process 23N and the post-annealing process 25 is performed after the second additional doping process 23P, the P-type contact resistance may be improved without deterioration of the N-type contact resistance.

The CMOSFET of the above-described embodiments may be applied as a part of a memory device, a logic device, or the like. For example, it may be applied as a peripheral circuit transistor of a memory device such as a dynamic random-access memory (DRAM), NAND, and a phase-change random-access memory (PCRAM). The memory cell array of the DRAM or the memory cell string of the NAND may be controlled by a peripheral circuit transistor.

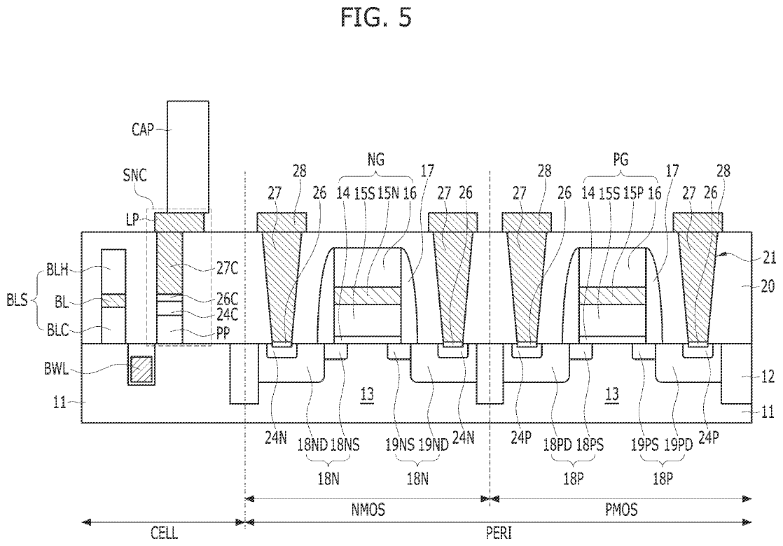

FIG. 5 is a diagram illustrating a semiconductor device according to another embodiment.

Referring to FIG. 5, a substrate 11 may include a cell region CELL and a peripheral circuit region PERI. The peripheral circuit region PERI is a region in which peripheral circuit transistors are formed. The peripheral circuit region PERI may include an NMOS region NMOS and a PMOS region PMOS. The cell region CELL may include a DRAM cell array or a NAND memory cell string. In this embodiment, the cell region CELL may be a part of a DRAM cell array.

The cell region CELL may include a bit line structure BLS and a storage node contact plug SNC formed on the substrate 11, a buried word line BWL buried in the substrate 11, and a capacitor CAP formed on the storage node contact plug SNC. The bit line structure BLS may have a stack structure of a bit line contact plug BLC, a bit line BL, and a bit line hard mask BLH. The storage node contact plug SNC may include a lower plug PP, an upper plug 27C on the lower plug PP, a landing pad LP on the upper plug 27C, and an ohmic contact layer 26C between the upper plug 27C and the lower plug PP. The lower plug PP may include doped polysilicon. The upper plug 27C and the landing pad LP may include a metal-based material. The ohmic contact layer 26C may include metal silicide such as cobalt silicide.

A detailed description of the transistors formed in the peripheral circuit area PERI will be described with reference to FIGS. 3A to 4D. An N-type gate stack NG of the NMOS region NMOS may include a stack in which a gate insulating layer 14, polysilicon 15S, an N-type metal layer 15N, and a gate capping layer 16 are stacked in the recited order. A P-type gate stack PG of the PMOS region PMOS may include a stack in which the gate insulating layer 14, the polysilicon 15S, a P-type metal layer 15P, and the gate capping layer 16 are stacked in the recited order. The N-type metal layer 15N may be a metal engineered to have an N-type work function, and the P-type metal layer 15P may be a metal engineered to have a P-type work function.

In another embodiment, the N-type metal layer 15N and the P-type metal layer 15P may be the same metal material. In this case, the N-type gate stack NG and the P-type gate stack PG may be engineered to have an N-type effective work function and a P-type effective work function, respectively. For example, in the N-type gate stack NG, an N-type capping layer may be formed between the gate insulating layer 14 and the polysilicon 15S. In the P-type gate stack PG, the P-type gate capping layer may be formed between the gate insulating layer 14 and the polysilicon 15S. The N-type capping layer may include lanthanum or lanthanum oxide, and the P-type capping layer may include aluminum or aluminum oxide.

An N-type additional doped region 24N may be formed on the surface of the N-type source/drain region 18N, and a P-type additional doped region 24P may be formed on the surface of the P-type source/drain region 18P. Metal silicide 26 may be formed on both the N-type additional doped region 24N and the P-type additional doped region 24P. A contact plug 27 may be formed on the metal silicide 26, and a metal interconnection 28 may be formed on the contact plug 27. The contact plug 27 and the metal interconnection 28 may be, for example, a stack structure of titanium nitride and tungsten (TiN/W).

The polysilicon 15S of the N-type gate stack NG and the P-type gate stack PG may be made of the same material also used for the bit line contact plug BLC. The N-type metal layer 15N of the N-type gate stack NG and the P-type metal layer 15P of the P-type gate stack PG may be made of the same material also used for the bit line BL.

The ohmic contact layer 26C of the storage node contact plug SNC and the metal silicide 26 of the peripheral circuit region PERI may be formed at the same time. The upper plug 27C of the storage node contact plug SNC and the contact plugs 27 of the peripheral circuit region PERI may be formed at the same time. The landing pad LP of the storage node contact plug SNC and the metal interconnection 28 of the peripheral circuit region PERI may be formed at the same time.

While forming the N-type and P-type additional doped regions 24N and 24P, additional dopants may be doped on the surface of the lower plug PP of the cell region CELL. For example, while forming the N-type additional doped region 24N, a cell additional doped region 24C may be formed by doping N-type additional dopants on the surface of the lower plug PP.

The above-described invention is not limited by the above-described embodiments and the accompanying drawings. It will readily be appreciated by one of ordinary skill in the art that various substitutions, changes, or modifications may be made thereto without departing from the scope of the disclosure.

What is claimed is:

1. A method for fabricating a semiconductor device, the method comprising:
forming a doped region by doping a first dopant in a substrate and activating the first dopant by an activation annealing process;
forming an interlayer insulating layer on the substrate;
forming a contact hole exposing the doped region by etching the interlayer insulating layer;
exposing the doped region to a pre-annealing process to form a pre-annealed doped region;
forming an additional doped region by doping a second dopant on the pre-annealed doped region;
exposing the additional doped region to a post-annealing process to form a post-annealed additional doped region; and
forming metal silicide on the post-annealed additional doped region.

2. The method of claim 1,
wherein the pre-annealing process and the post-annealing process include rapid thermal annealing, and,
wherein the pre-annealing process is performed at a higher temperature than the post-annealing process.

3. The method of claim 1, wherein the post-annealing process is performed at a lower temperature than the activation annealing process.

4. The method of claim 1, wherein the pre-annealing process is performed at a temperature reactivating the first dopant of the doped region.

5. The method of claim 1, wherein the pre-annealing process is performed at a temperature above 950° C., and the post-annealing process is performed at a temperature of 950° C. or lower.

6. The method of claim 1, wherein the first and second dopants include an N-type dopant.

7. The method of claim 1, wherein the first and second dopants include a P-type dopant.

8. The method of claim 1, wherein the pre-annealing process includes a rapid thermal process, and the post-annealing process includes a milli-second annealing performed for a shorter time than the pre-annealing process.

9. The method of claim 8, wherein the pre-annealing and the post-annealing process are performed at a temperature above 950° C., and wherein the post-annealing process is performed at a higher temperature and for a shorter time than the pre-annealing process.

10. A method for fabricating a semiconductor device, the method comprising:
forming an N-type source/drain region and a P-type source/drain region in a substrate;
forming an interlayer insulating layer on the substrate;
forming contact holes respectively exposing the N-type source/drain region and the P-type source/drain region by etching the interlayer insulating layer;
exposing the N-type and P-type source/drain regions to a pre-annealing process;
forming an N-type additional doped region by doping an N-type additional dopant in the pre-annealed N-type source/drain region;
forming a P-type additional doped region by doping a P-type additional dopant in the pre-annealed P-type source/drain region;
exposing the N-type and P-type additional doped regions to a post-annealing; and
forming a metal silicide on each of the post-annealed N-type and P-type additional doped regions.

11. The method of claim 10,
wherein the pre-annealing and the post-annealing processes include rapid thermal annealing, and
wherein the pre-annealing process is performed at a higher temperature than the post-annealing.

12. The method of claim 10, wherein the pre-annealing process is performed at a temperature reactivating the N-type and P-type source/drain regions.

13. The method of claim 10,
wherein the pre-annealing process is performed at a temperature above 950° C., and
wherein the post-annealing is performed at a temperature of 950° C. or lower.

14. The method of claim 10, wherein the forming of the P-type additional doped region includes sequentially performing germanium doping and boron-containing material doping on the pre-annealed P-type source/drain region.

15. The method of claim 10, after the exposing of the N-type and P-type source/drain regions to the pre-annealing process, wherein the N-type and the P-type source/drain regions have a carbon-free and a fluorine-free surface.

16. The method of claim 10, wherein the pre-annealing process is performed by a rapid thermal process, the post-annealing process is performed by a milli-second annealing for a shorter time than the pre-annealing.

17. The method of claim 16,
wherein the pre-annealing process and the post-annealing process are performed at a temperature above 950° C., and
wherein the post-annealing process is performed at a higher temperature and for a shorter time than the pre-annealing process.

18. A method for fabricating a semiconductor device, the method comprising:
forming an N-type source/drain region and a P-type source/drain region in a substrate;
forming an interlayer insulating layer on the substrate;
forming contact holes respectively exposing the N-type source/drain region and the P-type source/drain region by etching the interlayer insulating layer;
forming an N-type additional doped region by doping an N-type additional dopant in the N-type source/drain region;
exposing the N-type additional doped region, the N-type source/drain region, and the P-type source/drain region to a pre-annealing process;
forming a P-type additional doped region by doping a P-type additional dopant in the pre-annealed P-type source/drain region;
exposing the N-type and P-type additional doped regions to the post-annealing process; and
forming a metal silicide on the post-annealed N-type additional doped region and the post-annealed P-type additional doped region.

19. The method of claim 18,
wherein the pre-annealing process and the post-annealing process include rapid thermal annealing, and
wherein the pre-annealing process is performed at a higher temperature than the post-annealing.

20. The method of claim 18, wherein the pre-annealing process is performed at a temperature reactivating the N-type and P-type source/drain regions.

21. The method of claim 18,
wherein the pre-annealing process is performed at a temperature above 950° C., and
wherein the post-annealing process is performed at a temperature of 950° C. or lower.

22. The method of claim 18, wherein the forming of the P-type additional doped region includes sequentially performing germanium doping and boron-containing material doping on the pre-annealed P-type source drain region.

23. The method of claim 18, wherein
the substrate includes a cell region and a peripheral circuit region, and
the N-type source/drain region and the P-type source/drain region are formed in the peripheral circuit region.

24. The method of claim 23, wherein the cell region includes a dynamic random-access memory (DRAM) cell array or a NAND memory cell string.

25. The method of claim 18, wherein the pre-annealing process is performed by a rapid thermal process, and the post-annealing process is performed by a milli-second annealing for a shorter time than the pre-annealing process.

26. The method of claim 25,
wherein the pre-annealing process and the post-annealing process are performed at a temperature above 950° C., and
wherein the post-annealing process is performed at a higher temperature and for a shorter time than the pre-annealing process.
